(19) United States
(12) Patent Application Publication
(10) Pub. No.: US 2019/0149088 A1
(43) Pub. Date: May 16, 2019

(54) Integrated and portable outdoor compatible photo-voltaic device to convert and store solar energy into electrical energy for applications like lighting, charging USB based mobile devices / tablets and for operating small electrical appliances.

(71) Applicant: Adrija Chaturvedi, Cleveland, OH (US)

(72) Inventor: Adrija Chaturvedi, Cleveland, OH (US)

(21) Appl. No.: 16/153,744

(22) Filed: Oct. 6, 2018

Related U.S. Application Data
(60) Provisional application No. 62/707,717, filed on Nov. 15, 2017.

(51) Int. Cl. H02S 40/38; H02J 7/00; H02S 10/40; G01R 31/36

(52) U.S. Cl. CPC H02S 40/38; H02J 7/0027; H02S 10/40; H02J 2007/0059; H02J 7/007; H02J 2007/0062; G01R 31/36

(57) ABSTRACT

An integrated, outdoor compatible and portable solar photovoltaic device is made for USB based charging of mobile devices (i-phones/tablets/i-pads etc.) as well as for operating 12 V DC or mains voltage AC lighting and other small appliances. It can be used as an emergency power source for charging/operating these devices in case of sudden power interruption as well. This device, totally compatible with outdoor conditions of temperature extremes, snow, dust, rain, wind, hail, mud etc., is protected by an electrical fuse, a glowing “low battery charge” indicator and an hibernation/active switch. A toggle switch turns it in Lamp & USB charging mode when it is intended to be used.

With regular 6 hr charging in a sunny day or all day charging in a cloudy day, 30 Wh energy can be used daily without harming the 60 Wh sealed battery's working life. Occasionally, much higher Wh can be consumed. The device is wired in such a way that it is always charged as the solar panel is always connected with the battery through the charge controlling device. In another embodiment, 12 VDC outlet is not provided but the regular USB charging system is replaced with a more powerful charger so that USB charging gadgets are charged much quickly, almost like their wall plug charging. 120V/60 Hz, 230V/50 Hz or any other AC line voltage and frequency can be obtained in yet another embodiment using an appropriate “modified” or “pure sine wave” type inverter intrinsic in it. This embodiment may or may not have an USB charging port and is fully scalable to a portable micro-grid storing more solar energy and power.

The energy (Wh) going in/from this device during its charging/discharging can be monitored remotely on an smart phone using an intrinsic Blue-tooth broadcaster fitted in it with current and voltage monitoring sensors and a microprocessor. All the embodiments described here can have this capability.

### BACKGROUND OF THE INVENTION AND PRIOR ART

Storing the electrical (DC) output of a solar panel when it is exposed to sunlight, in a rechargeable battery, is the oldest method of storing solar electrical energy and became popular as soon as efficient and cost-effective solar panels became available. Furthermore, the technique became wide spread at different commercial scales within the past few decades, slowly but steadily, as the solar panels, charge storing batteries, solar charge controllers and other related electronics became more and more efficient, ruggedized and cost effective.

On a small scale, where the demand of stored energy is only ^{˜}10 Wh (such as operating emergency LED lights or charging mobile devices) several solar energy storage devices suddenly appeared in the market. They mostly encompassed two categories: (1) for emergency lighting and (2) for charging mobile devices and tablets. The 1^{st} category, which also sometimes included outdoor solar lighting, was developed as a weather resistant system, while the second included devices that were very light so the owner could use them while sitting or walking outside in the sun, and so were not made to be weather resistant. In many cases, they were not equipped with an energy storage system, as the mobile devices were only meant to be connected while the solar charger was exposed to the sun. In cases where an energy-storage battery was provided, it was a small lightweight Li-ion Battery. Although the Li-ion battery has many merits, a major limitation is that it is restricted in air transportation.

Unattended, portable, outdoor weather-compatible small solar energy storage devices that can be left outside for charging and can be used indoor or outdoor when needed, are rare. U.S. Pat. No. 8,319,470 B2 (and references therein) describes such a versatile device, but does not express its capability to remain outdoors for extended periods of time in harsh conditions (extraordinary temperatures, rain, snow, hail, dust and other weathering extremes) without losing its appearance and functionality. Therefore, one must assume that devices such as this must be attended while they are put outdoors for charging.

In another recent patent (US Patent #2018/0128438 A1, Publication Date: May 10, 2018) an interesting and complicated collapsible-expandable photovoltaic device is described having sealed storage battery and electronics. For solar charging, it has to be collapsed or expanded to make it flat. In outdoor, light flat things can fly easily in windy environment or can flip putting the solar panel upside down. How water ingress is avoided in this device is not explained fully.

In a very recent patent (U.S. patent Ser. No. 10/084,213 B2 Dated Sep. 25, 2018) a briefcase/suitcase type, very versatile, portable renewable energy power system is described. It has a lot of options including mains line as well as solar panel charging of its battery. Although its exposure of outer elements such as snow, wind, rain etc. is mentioned, how it faces all these elements without sealing the battery's container hermetically, is not elaborated. In deployable solar panels mode of this device, the briefcase has to be opened and water ingress prevention in this situation is not mentioned.

Our present invention is aimed to build a portable, compact solar energy harnessing and storing device which can withstand extreme outdoor conditions while totally unattended and can be used either daily or occasionally, indoor or outdoor.

### SUMMARY OF THE INVENTION

We have invented a compact portable device which harnesses and stores solar energy in it and can tolerate extreme outdoor conditions, needing practically no attention. Energy storage battery is always connected to the solar panel and so, it charges the battery even if the intensity of the sunlight is very low. A red glow appears in one corner of the solar panel (can be seen easily in dark) when the battery charge is very low. A protection device will cut the output current if it is used in this condition. As soon as the device is charged sufficiently again in sunlight, the red glow will disappear and the device is ready again for the intended use. This invented device can give 12V DC or mains line voltage/frequency AC (AC voltage and frequency of its final destination) with USB charging voltage.

### BRIEF DESCRIPTIONS OF DRAWINGS

The advantage of the invention will be more apparent to those skilled in the art with the detailed description of the invention in which;

The 1^{st} embodiment of the invented device is shown in FIGS. 1A, 1B and 1C. FIG. 1A is the front isometric view of whole device while FIG. 1B is as it is viewed from the top (solar panel 2 removed). FIG. 1C is a cut view from front side (solar panel 2 removed). We can get 12V DC output for LED/CFL lighting and USB charging power for mobile devices (e.g. i-phones/i-pads etc.) from this embodiment.

FIG. 2 is the isometric view of the rear side of the 1^{st} embodiment.

FIG. 3 is the front isometric view of the 2^{nd} embodiment of the device. It has higher power USB charger but does not have 12 V DC outlet.

FIG. 4 is 3^{rd} embodiment of the invention where we can get the mains line voltage and frequency of a particular country/region from this device and also USB ports for charging mobile devices (e.g. i-phones/tablets/i-pads etc.). This embodiment is like a micro-grid.

FIG. 5 is the block circuit diagram of 1^{st} embodiment having 12V DC and USB charging outlets.

FIG. 6 is the block circuit diagram of 3rd embodiment giving mains line voltage/frequency and quicker USB charging power. Some passive components (LED indicator, cooling fan etc.) are not shown in this block circuit diagram.

FIG. 7 is the block circuit diagram for monitoring charged/discharged energy (Wh) in this invention using a Bluetooth device embedded in the device. It can be installed in all embodiments of the device.

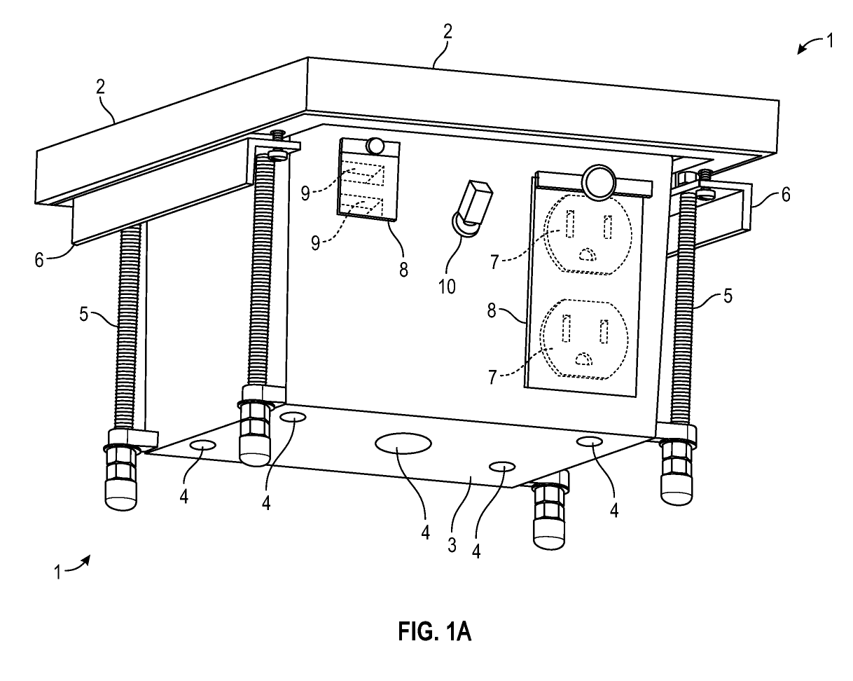

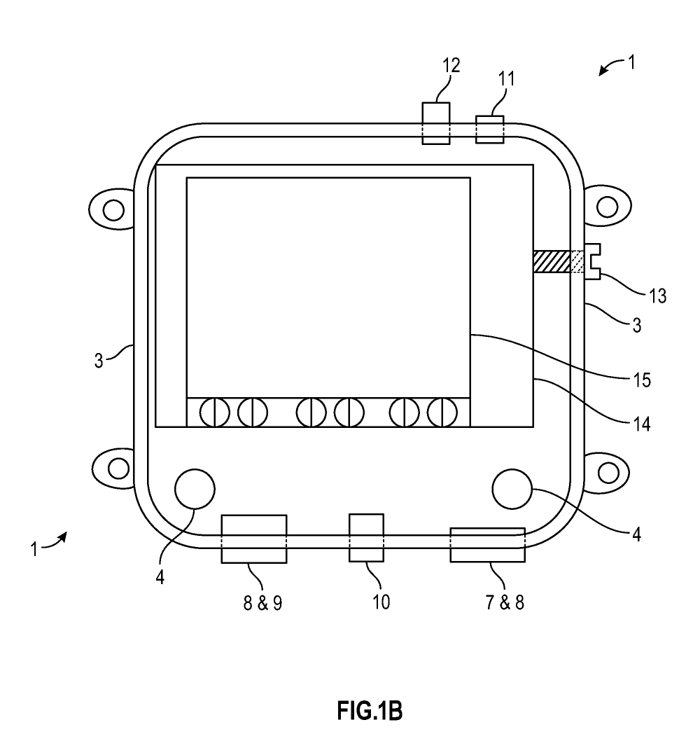

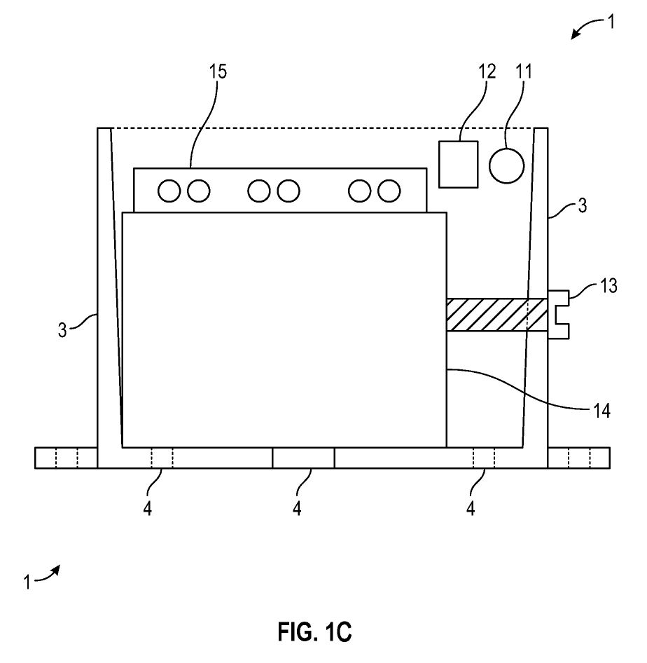

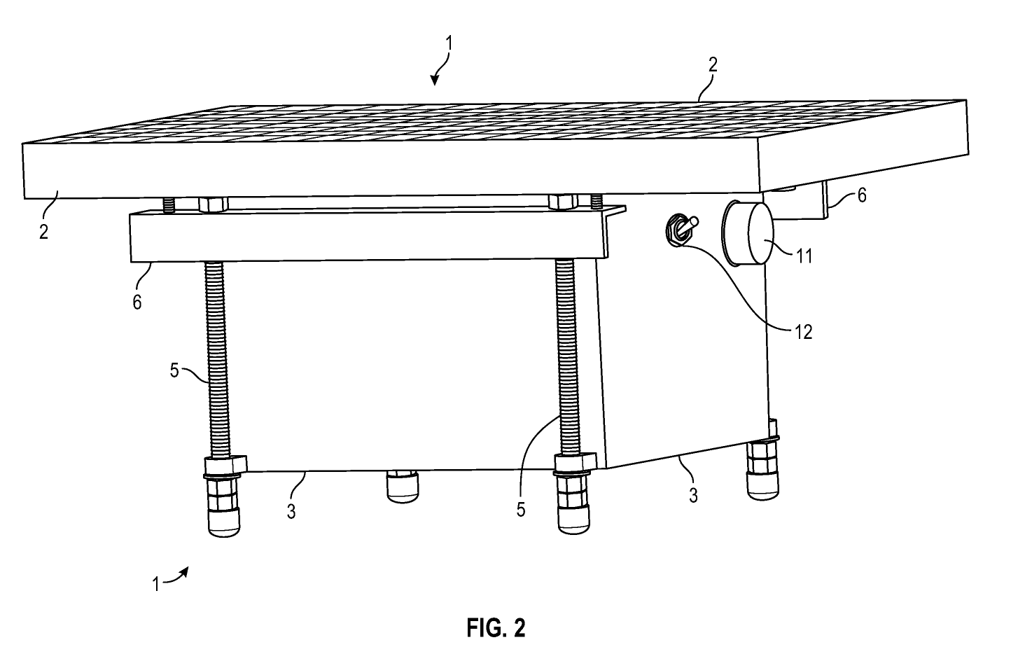

### DETAILED DESCRIPTION OF PREFERRED EMBODIMENTS

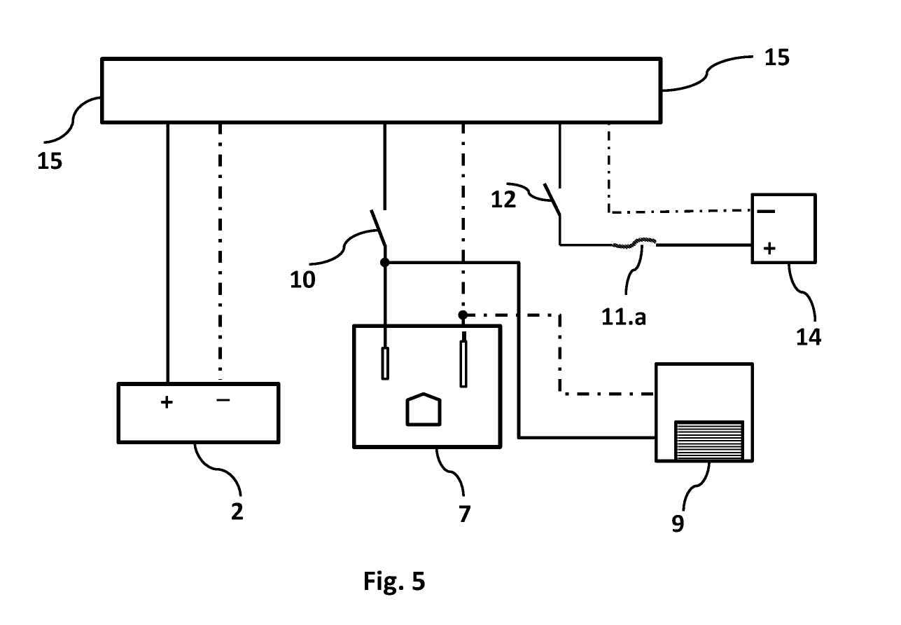

In one and most versatile 1^{st} embodiment (FIGS. 1A, 1B, 1C and its block circuit diagram FIG. 5), an outdoor compatible electrically insulating plastic box 3, having water drainage hole in the bottom 4 and several holes/cutouts on its front and rear walls, is equipped with a solar panel 2, handling right-angle bars 6 and fastening stand bolts 5. The solar panel 2 and the plastic box 3 are attached by appropriate screws with the handling right-angle bars 6 and stand bolts 5 in such a way that the rear surface of the solar panel covers the box 3 tightly protecting it from rain water ingress from the top while most of the system's load does not heart the fragile and thin aluminum solar panel frame while handling the system manually. Further protection from rain/water ingress is provided by elastomeric screens 8 covering the rectangular cutouts where a regular US double socket polarized wall plug 7 and a 12 to 5 V DC to DC converter having 2 charging USB ports 9 is mounted with the wall of the box, behind the elastomeric screens 8. A toggle switch 10 puts the system in discharge mode whenever it is needed for operating lighting bulbs and/or for charging of USB based mobile devices etc. Elastomeric screens 8 can be bent upward lifting its lower end upside for connecting a suitable plug in these outlets.

Stand bolts 5 (and parts with it) keep the bottom of the box 3 about 1 inch above the ground so that water flowing on the earth surface does not inter in the box 3 through drains holes 4. In case of heavy rain, if there is some water ingress in the box, it will be drained through drainage holes 4. Mounting of the wetting/moisture sensitive electricals/electronics components 7, 9, 10, 15 in the box 3 at places away from the box's bottom gives further safety to these components from wetting. The SLA battery 14 is heavy and is mounted on the bottom surface of the box 3, fastened on its position by a screw 13. This puts the center of gravity of the device near the bottom of the box and so, it does not topple even when it faces high speed wind gusts outdoor.

On the rear wall, a toggle switch 12 puts the system in “active” or “hibernation” mode connecting/disconnecting the battery 14 from the rest of the components. In hibernation mode, battery cannot be charged or discharged and can maintain its charge state for weeks. A fuse holder and fuse 11, 11.a is also mounted on this wall. The fuse (11, 11.a) protects the electronics if too high current is withdrawn from the battery (14) due to any reason.

The electrical wiring block diagram of this embodiment is shown in FIG. 5. Energy storage battery 14 is connected to the solar charge controller (battery terminals) 15 through the fuse 11.a and hibernation/active toggle switch 12. Solar panel 2 is connected to solar charge controller 15 on it's appropriate terminals while the US double socket standard polarized wall plug 7 is connected with the load terminals of the solar charge controller 15 through a toggle switch 10. In parallel, the 12V to 5 V DC to DC transformer having 2 USB charging ports 9 is also connected as shown in FIG. 5. The toggle switch 10 connects or disconnects both of these loads with the solar charge controller 15.

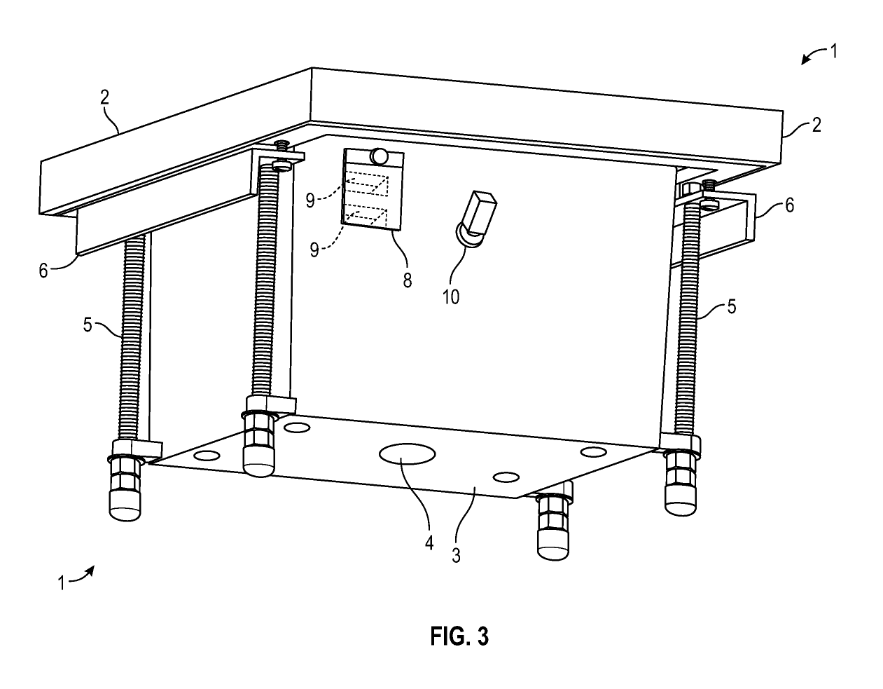

In 2^{nd} embodiment (FIG. 3), a much faster mobile charging device is used. This system has no 12 V DC outlet (7). 12V to 5V DC to DC converter having USB ports 9 is more powerful in this embodiment and hence the charging is much faster, almost as fast as if it is done using a wall plug charger.

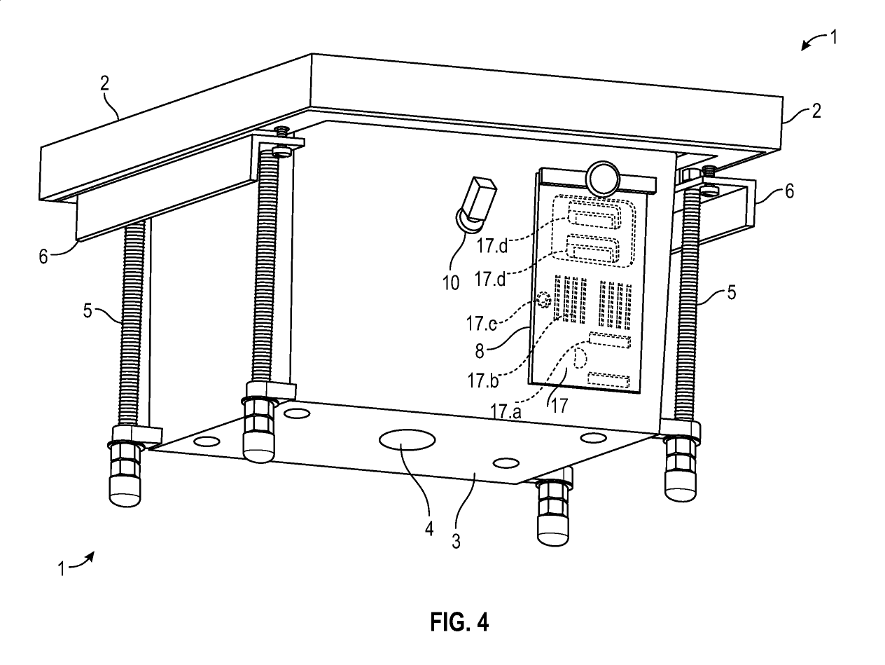

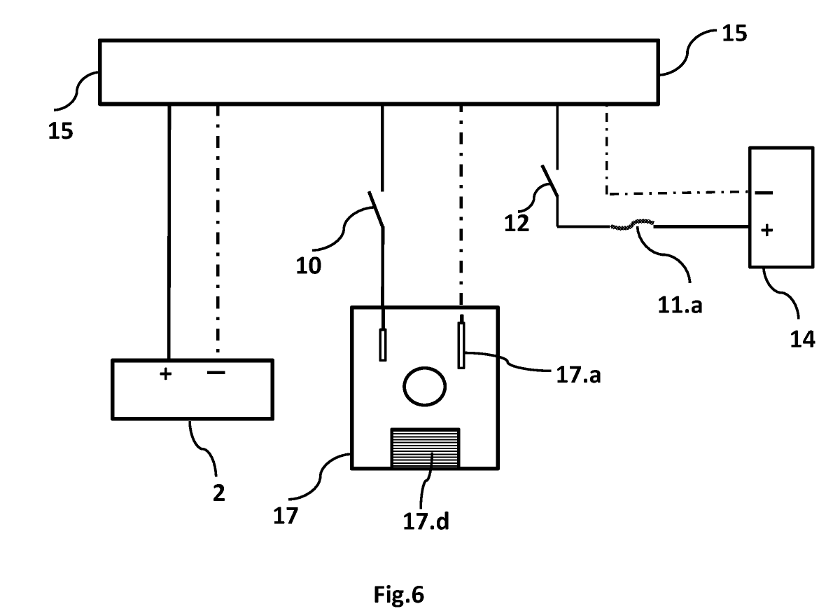

The 3^{rd} embodiment is shown in FIG. 4 and its block electrical circuit diagram in FIG. 6. A special 12V DC input inverter 17 generate AC electricity of that particular region (e.g. 120 V 60 Hz for USA) and has a standard outlet 17.a of that particular region/country. It may have a USB charger port 17.d as well with a LED indicator 17.c. In some cases, depending on the power output and duty-cycle, it may have a small cooling fan hidden behind the ventilation window 17.b. All this is hidden behind the elastomeric screen 8 so that it is protected from water ingress, like in other aforesaid embodiments. This embodiment gives USB as well as regular AC outlet. Practically any mobile device can be charged and any low wattage electrical gadget can be connected with it and can be operated for short time. The inverter 17 may be a “modified sine wave” or “pure sine wave” type. So, this embodiment is like a household micro-grid.

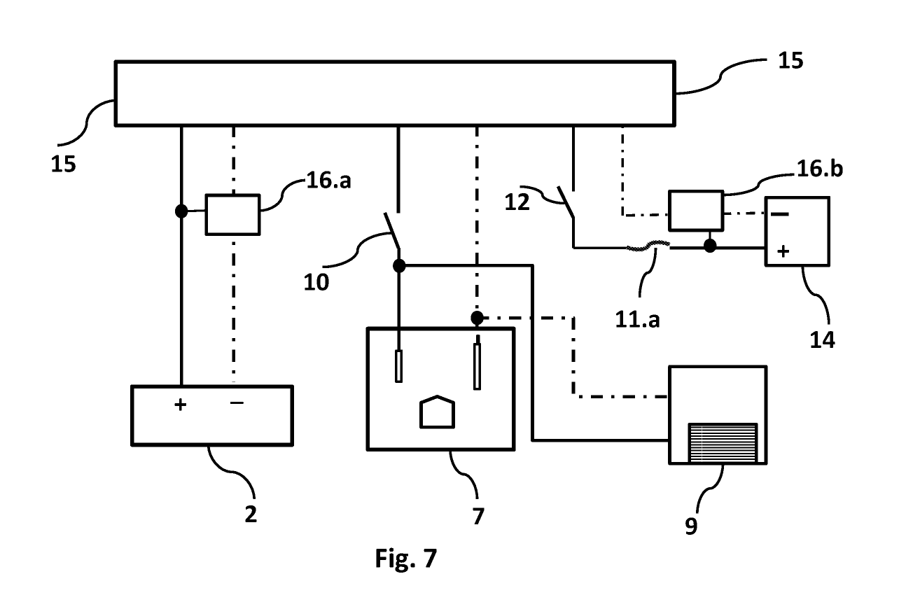

In FIG. 7, we propose a method for remote monitoring of the charge state and electrical charge flow in this gadget when it is being charged in sun or is being used. A Hall/Resistor current sensor measures the current flowing in the battery 14 from the solar panel 2 while charging and from battery 14 to loads (7, 9) while discharging. The voltage is also sensed by an ADC and a microcontroller calculates the W and Wh at preset intervals. The integrated energy (Wh) is broadcasted by a low power Bluetooth which can be received on a smart-phone or computer (if it is in its range: 100′ or so). All these are packed in a small plastic boxes 16.a and 16.b. The plastic box is insulating and so does not stop the Bluetooth radio waves and does not need any RF emission outlet/antenna.

1. We claim to invent an integrated, outdoor compatible and portable device which collects solar energy for charging a sealed battery and for delivering USB charging voltage and DC or AC electrical energy for different purposes whenever it is needed.

2. It comprises a weather resistant plastic box, a solar panel, a sealed lead acid (SLA) battery, a solar charge controller, DC to DC and DC to AC transformers, polarized regular and USB electrical output sockets, fuse and toggle switches, handling bars and standoff bolts etc. Hence:
1. We claim that the aforesaid device can be used for operating 12 VDC or mains line AC voltage appliances and for USB based charging of mobile devices e.g. i-phones, tablets, i-pads etc.
2. We claim that the aforesaid device can be left unattended in outdoor environment for charging by solar light. This device is capable to tolerate rain, wind, moisture, dust, mud, solar ultraviolet etc., without losing its functionality and appearance throughout its life. When not in use, this device can be stored outdoor for months, totally unattended.
3. We claim that the aforesaid device is always charging its battery through its charge controller whenever it is exposed to any intensity of light and so, can be left unattended outdoor for weeks/months without appreciable degradation in its performance.
4. We claim that the aforesaid device, having sealed lead acid (SLA) battery inside for electrical energy storage, is very safe and transportable by surface and air.
5. We claim that the aforesaid device has a Hibernation switch and if long term non-functional state is needed, it can be done easily without losing battery's electrical charge/life.
6. We claim that the aforesaid device is not hermetically sealed and is well ventilated complying safety rules for using any sealed energy storage battery in such an application.
7. We claim that the aforesaid device is easily scalable for higher electrical energy and higher electrical power output.
8. We claim that the aforesaid device can be equipped/modified for the electrical standards of the destination country/region.
9. We claim that the aforesaid device can be used as part of an emergency kit during power outage which can provide enough energy/power to have some lighting and for charging mobile devices.
10. We claim that in the aforesaid device, a red glow appears in one corner of the solar panel (easily visible in dark) when its battery is too much discharged. If used in that state any further, its charge controller will shut off the output current protecting life of the battery.
11. We claim that when the aforesaid device, having red glow on the solar panel when its battery is too much discharged, is sufficiently charged again in sun, the red glow will disappear and the device is again ready for its intended use.
12. We claim that the aforesaid device can be equipped with a Hall/resistor current meter, Analog to Digital Converter (ADC), micro-processor and Bluetooth system so that the total energy stored/discharged in/from this device while charging/discharging can be monitored remotely using a smart phone/tablet/computer.
